(19) United States
(12) Patent Application Publication
(10) Pub. No.: US 2021/0357046 A1
(43) Pub. Date: Nov. 18, 2021

(54) CAPACITIVE TOUCH DISPLAY SCREEN AND DISPLAY

(71) Applicant: HUIZHOU CHINA STAR OPTOELECTRONICS TECHNOLOGY CO., LTD., Huizhou (CN)

(72) Inventors: Chingyuan CHEN, Huizhou (CN); Quan LI, Huizhou (CN); Guofu TANG, Huizhou (CN); Yuchun HSIAO, Huizhou (CN); Weifeng CHEN, Huizhou (CN)

(73) Assignee: HUIZHOU CHINA STAR OPTOELECTRONICS TECHNOLOGY CO., LTD., Huizhou (CN)

(21) Appl. No.: 16/618,807

(22) PCT Filed: Sep. 11, 2019
(86) PCT No.: PCT/CN2019/105267

§ 371 Date: Dec. 3, 2019

(30) Foreign Application Priority Data
Jul. 5, 2019 (CN) 201910602164.4

(51) Int. Cl. G06F 3/044; G02F 1/1333; G02F 1/1335; H01L 27/32

(52) U.S. Cl. CPC G06F 3/044; G02F 1/13338; H01L 27/323; G02F 1/133502; G02F 1/133331

(57) ABSTRACT

A capacitive touch display screen and a display are provided. The capacitive touch display screen consists of a touch conductive film and a display module bonded with each other. A capacitive touch display comprises the capacitive touch display screen and a cover disposed thereover.

### FIELD OF INVENTION

The present invention relates to display technologies, and more particularly to a capacitive touch display screen and a display.

### BACKGROUND

A touch display is an inductive display device capable of receiving input signals such as contacts, and has advantages of being instinctive, simple, and quick. Touch screens have been widely used in many electronic devices, such as cell phones, tablets, multimedia, public information query systems, and the like.

A capacitive touch conductive film on the market is bonded to glass cover to form a touch cover, and the touch cover is then bonded to a liquid crystal panel by full lamination or edge lamination. However, this design results in simplification of the product specification that makes no product differentiation between end products. In addition, it is unable to change the cost structure, resulting in prices not meeting market expectations.

Therefore, it is necessary to develop a new type capacitive touch display to overcome the drawbacks of the existing technologies.

### Technical Problem

An object of the present invention is to provide a touch display that can solve the problems of simplification of the product specification, high cost, and the like, which is caused bonding of the capacitive touch conductive film to the glass cover in the existing technologies.

### Solution to Problem

To achieve the above object, the present invention provides a capacitive touch display screen comprising a touch conductive film and a display module bonded to each other.

Furthermore, in other embodiments, the display module is a liquid crystal display panel.

Furthermore, in other embodiments, the display module is an organic light-emitting diode (OLED) display panel.

To achieve the above objective, the present invention provides a capacitive touch display, comprising a capacitive touch display screen and a cover disposed thereover.

Furthermore, in other embodiments, the cover is an anti-glare (AG) film, and the capacitive touch display screen is bonded to the AG film.

Furthermore, in other embodiments, the cover is a glass cover.

Furthermore, in other embodiments, the touch display screen is bonded to the glass cover by edge lamination.

Furthermore, in other embodiments, the touch display screen is bonded to the glass cover by full lamination

Furthermore, in other embodiments, the glass cover is a tempered glass cover.

Furthermore, in other embodiments, the optical glue is an optically clear adhesive.

Furthermore, in other embodiments, the display module is a liquid crystal display panel.

Furthermore, in other embodiments, the display module is an organic light-emitting diode (OLED) display panel.

To achieve the above objective, the present invention provides a capacitive touch display device, comprising a body, wherein the body is provided with the capacitive touch display of the present application.

### Advantageous Effects

Compared with the present techniques, the present invention has the beneficial effects of providing a capacitive touch display screen and a display, and the touch conductive film is bonded to the display module, and the attachment can be used to form end products by bonding of AG film, edge lamination of a glass cover, or full lamination of a glass cover based on various usages. This architecture can make different product specifications according to different market requirements, and corresponding to different costs, while maintaining maximum product sharing, reducing inventory costs and saving costs.

### BRIEF DESCRIPTION OF DRAWINGS

To detailly explain the technical schemes of the embodiments or existing techniques, drawings that are used to illustrate the embodiments or existing techniques are provided. Apparently, the illustrated embodiments are just a part of those of the present disclosure. It is easy for any person having ordinary skill in the art to obtain other drawings without labor for inventiveness.

FIG. 1 is a schematic structural diagram of a capacitive touch display screen according to an embodiment 1 of the present invention.

FIG. 2 is a schematic structural diagram of a capacitive touch display according to the embodiment 1 of the present invention.

FIG. 3 is a schematic structural diagram of a capacitive touch display according to an embodiment 2 of the present invention.

FIG. 4 is a schematic structural diagram of a capacitive touch display according to an embodiment 3 of the present invention.

Descriptions of the reference numbers in the figures are:

1: capacitive touch display screen; 2: anti-glare (AG) film; 3: glass cover; 4: optical glue; 5: liquid crystal display; 6-12: touch conductive film.

### DETAILED DESCRIPTION

The technical solutions in the embodiments of the present invention are clearly and completely described in the following with reference to the accompanying drawings in the embodiments of the present invention. It is obvious that the described embodiments are only a part of the embodiments of the present invention, but not all embodiments. All other embodiments obtained by those skilled in the art based on the embodiments of the present invention without labor for inventiveness are within the scope of the present invention.

The specific structural and functional details disclosed are merely representative and are for the purpose of describing exemplary embodiments of the invention. The present invention may, however, be embodied in many alternative forms and should not be construed as being limited only to the embodiments set forth herein.

### Embodiment 1

The capacitive touch conductive film in current technologies is bonded to a glass cover to form a touch cover, and the touch cover is then bonded to a liquid crystal panel by full lamination or edge lamination. However, this design results in simplification of the product specification that makes no product differentiation between the end products. In addition, it is unable to change the cost structure, resulting in prices not meeting market expectations

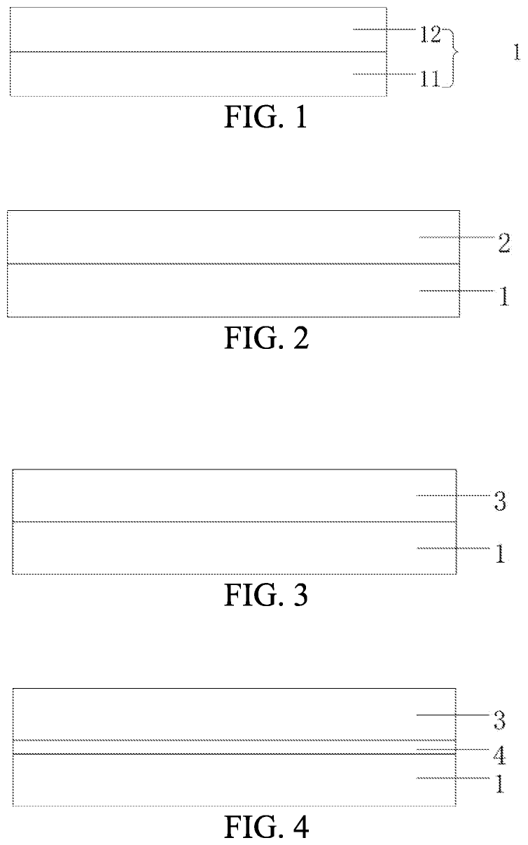

The present embodiment provides a capacitive touch display screen. Referring to FIG. 1, FIG. 1 is a schematic structural diagram of a capacitive touch display screen 1 according to the present embodiment, which comprises a liquid crystal display panel 11 and a touch conductive film 12 disposed over the liquid crystal display panel 11. The liquid crystal display panel 11 and the touch conductive film 12 are bonded to each other.

In other embodiments, the liquid crystal display panel may be replaced by an organic light-emitting diode (OLED) to function as an OLED display panel, which may be determined as needed, and is not limited herein.

According to different usages, the capacitive touch display screen 1 can be bonded to different covers to make it an end product.

The present embodiment further provides a capacitive touch display. Referring to FIG. 2, FIG. 2 is a schematic structural diagram of a capacitive touch display according to this embodiment. The capacitive touch display comprises the capacitive touch display screen 1 of the above-mentioned embodiment and an anti-glare (AG) film 2 disposed over the capacitive touch display screen 1. The AG film 2 is bonded to the capacitive touch display screen 1, and the AG film is a frosted anti-reflection film.

Since the capacitive touch display provided by the embodiment is formed by bonding the AG film 2 to the capacitive touch display screen 1, the cost is relatively low, and it belongs to a low end product, and can be applied to the market while there is not much demand for the quality of the capacitive touch control display, and the cost budget is relative low.

### Embodiment 2

The present embodiment further provides a capacitive touch display. Referring to FIG. 3, FIG. 3 is a schematic structural diagram of a capacitive touch display according to the present embodiment. The capacitive touch display comprises the capacitive touch display screen 1 of the above-mentioned embodiment and a glass cover 3 disposed over the capacitive touch display screen 1. The glass cover 3 is bonded to the capacitive touch display screen 1 by edge lamination. The edge lamination uses a frame-shaped adhesive to bond the capacitive touch display screen 1 to the glass cover 3, and the frame-shaped adhesive is hidden in an ink area of the capacitive touch display screen 1.

In this embodiment, the glass cover 2 is a tempered glass cover.

The capacitive touch display provided by this embodiment is formed by attaching the glass cover 3 and a frame of the capacitive touch display screen 1, so the cost is relatively moderate, and it is for middle-end products, and can be used in the market while there is moderate demand for the quality of the capacitive touch control display, and the cost budget is relatively moderate.

### Embodiment 3

The present embodiment further provides a capacitive touch display. Referring to FIG. 4, FIG. 4 is a schematic structural diagram of a capacitive touch display according to present embodiment. The capacitive touch display comprises the capacitive touch display screen 1 of the above-mentioned embodiment and the glass cover 3 disposed over the capacitive touch display screen 1, the glass cover 3 is bonded to the capacitive touch display screen 1 by full lamination through the optical glue 4. Full lamination means that the contact surfaces on both sides that are bonded to each other are fully coated with glue and with no gaps.

In this embodiment, the optical glue 4 is an optically clear adhesive (OCA).

The capacitive touch display provided by this embodiment is made of the glass cover 3 and the capacitive touch display screen 1 by full lamination through the optical glue 4, so the cost is relatively high, and it is for high-end products, and can be used in the market while there is higher demand for the quality of the capacitive touch control display, and the cost budget is relatively moderate.

The present invention has the beneficial effects of providing a capacitive touch display screen and a display, and the touch conductive film is bonded to the display module, and bonding can be used to form end products by attachment of AG film, edge lamination of glass cover, or full lamination of glass cover based on various usages. This architecture can make different product specifications according to different market requirements, and corresponding to different costs, while maintaining maximum product sharing, reducing inventory costs, and saving costs.

While the present disclosure has been described with the aforementioned preferred embodiments, it is preferable that the above embodiments should not be construed as limiting of the present disclosure. Anyone having ordinary skill in the art can make a variety of modifications and variations without departing from the spirit and scope of the present disclosure as defined by the following claims.

What is claimed is:

1. A capacitive touch display screen, comprising a touch conductive film and a display module bonded to each other.

2. The capacitive touch display screen of claim 1, wherein the display module is a liquid crystal display panel.

3. The capacitive touch display screen of claim 1, wherein the display module is an organic light-emitting diode (OLED) display panel.

4. A capacitive touch display, comprising the capacitive touch display screen of claim 1 and a cover disposed thereover.

5. The capacitive touch display of claim 4, wherein the cover is an anti-glare (AG) film, and the capacitive touch display screen is bonded to the AG film.

6. The capacitive touch display of claim 4, wherein the cover is a glass cover.

7. The capacitive touch display of claim 6, wherein the touch display screen is bonded to the glass cover by edge lamination.

8. The capacitive touch display of claim 6, wherein the touch display screen is bonded to the glass cover by full lamination.

9. The capacitive touch display of claim 6, wherein the glass cover is a tempered glass cover.

10. The capacitive touch display of claim 8, wherein the optical glue is an optically clear adhesive.

11. The capacitive touch display of claim 4, wherein the display module is a liquid crystal display panel.

12. The capacitive touch display of claim 4, wherein the display module is an organic light-emitting diode (OLED) display panel.

13. A capacitive touch display device, comprising a body, wherein the body is provided with the capacitive touch display of claim 4 thereover.

14. The capacitive touch display device of claim 13, wherein the cover is an anti-glare (AG) film, and the touch display screen and the AG film are bonded.

15. The capacitive touch display device of claim 13, wherein the cover is a glass cover.

16. The capacitive touch display device of claim 15, wherein the touch display screen is bonded to the glass cover by edge lamination.

17. The capacitive touch display device of claim 15, wherein the touch display screen bonded to the glass cover by full lamination through an optical glue.

18. The capacitive touch display device of claim 15, wherein the glass cover is a tempered glass cover.

19. The capacitive touch display device of claim 17, wherein the optical glue is an optically clear adhesive.

20. The capacitive touch display device of claim 13, wherein the display module is a liquid crystal display panel.
